(19) United States
(12) Patent Application Publication
(10) Pub. No.: US 2018/0196722 A1
(43) Pub. Date: Jul. 12, 2018

(54) Data Storage Device and Data Maintenance Method Thereof

(71) Applicant: Silicon Motion, Inc., Jhubei City (TW)

(72) Inventor: Wen-Sheng Lin, Kaohsiung City (TW)

(73) Assignee: Silicon Motion, Inc.

(21) Appl. No.: 15/662,842

(22) Filed: Jul. 28, 2017

(30) Foreign Application Priority Data
Jan. 9, 2017 (TW) 106100592

(51) Int. Cl. G06F 11/14; G11C 7/20; G06F 12/02; G11C 29/52

(52) U.S. Cl. CPC G06F 11/1469; G11C 7/20; G06F 12/0246; G11C 29/52; G06F 12/0292

(57) ABSTRACT

The present invention provides a data storage device including a flash memory and a controller. The controller writes a data sector into a specific page of a specific block of the flash memory, and determines whether the specific block was undergoing a write operation at the time that a power-off event occurred after the data sector is written into the specific page, wherein the controller determines whether to read the data sector from the specific block according to whether the specific block was undergoing a write operation at the time that the power-off event occurred to confirm whether the data sector was successfully written into the specific page.

### CROSS REFERENCE TO RELATED APPLICATIONS

This Application claims priority of Taiwan Patent Application No. 106100592, filed on Jan. 9, 2017, the entirety of which is incorporated by reference herein.

### BACKGROUND OF THE INVENTION

### Field of the Invention

The present invention is related to a data storage device, and in particular to a data storage device capable of maintaining write performance.

### Description of the Related Art

Flash memory is considered a non-volatile data-storage device, using electrical methods to erase and program itself. NAND Flash, for example, is often used in memory cards, USB flash devices, solid state devices, eMMCs, and other memory devices.

Flash memory such as NAND Flash uses a multiple-block structure to store data, wherein flash memory uses floating gate transistors. The floating gates of the floating gate transistor may catch electronic charges for storing data. The method used to write data into the flash memory influences the write performance. Therefore, it is important to design an efficient and safe write method.

### BRIEF SUMMARY OF THE INVENTION

A detailed description is given in the following embodiments with reference to the accompanying drawings.

An exemplary embodiment provides a data storage device including a flash memory and a controller. The flash memory has a plurality of blocks, and each of the blocks has a plurality of pages. The controller writes a data sector into a specific page of a specific block, and determines whether the specific block was undergoing a write operation at the time that a power-off event occurred after the data sector is written into the specific page, wherein the controller determines whether to read the data sector from the specific block according to whether the specific block was undergoing a write operation at the time that the power-off event occurred to confirm whether the data sector was successfully written into the specific page.

Another exemplary embodiment provides a data maintenance method applied to a data storage device having a flash memory. The data maintenance method includes: writing a data sector into a specific page of a specific block of the flash memory; after the data sector is written into the specific page, determining whether the specific block was undergoing a write operation at the time that a power-off event occurred; and determining whether to read the data sector from the specific block according to whether the specific block was undergoing a write operation at the time that the power-off event occurred to confirm whether the data sector was successfully written into the specific page.

### BRIEF DESCRIPTION OF THE DRAWINGS

The present invention can be more fully understood by reading the subsequent detailed description and examples with references made to the accompanying drawings, wherein:

FIG. 1 is a schematic diagram illustrating an electronic system in accordance with an embodiment.

FIG. 2 is a flowchart of a data maintenance method in accordance with an embodiment.

FIG. 3 is a flowchart of a data maintenance method in accordance with another embodiment.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

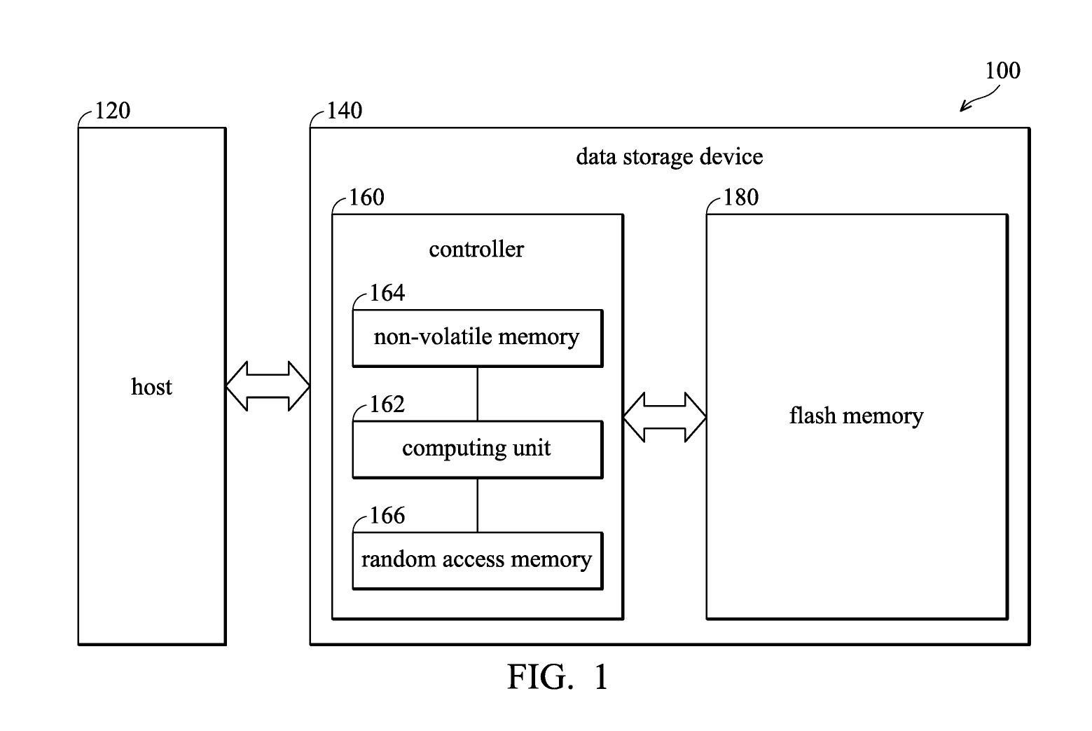

FIG. 1 is a schematic diagram illustrating an electronic system in accordance with an embodiment. The electronic system 100 includes a host 120 and a data storage device 140. The data storage device 140 includes a flash memory 180 and a controller 160, and operates in response to the commands of the host 120. The controller 160 includes a computing unit 162, a non-volatile memory 164 (ROM) and a random access memory 166 (RAM). The non-volatile memory 164, the program code stored in the non-volatile memory 164 and data stored in the non-volatile memory 164 constitute firmware executed by the processing unit 162, and the controller 160 is configured to control the flash memory 180 based on the firmware. The random access memory 166 is arranged to load program codes and parameters for the controller 160. The flash memory 180 includes a plurality of blocks, and each of the blocks includes a plurality of pages. It should be noted that the minimum write unit of the flash memory 180 is a page, and the minimum erase unit of the flash memory 180 is a block.

In one embodiment, the controller 160 builds a physical-to-logical mapping table in the random access memory 166 to record the relationships of the physical addresses of the pages and the logical addresses of the pages of data. When a power-off event occurs, the physical-to-logical mapping table stored in the random access memory 166 and the temporary-block table will be lost. Therefore, when the data storage device 140 resumes operation after a power-off event, the controller 160 needs to read the pages of blocks in sequence to rebuild the physical-to-logical mapping table in the random access memory 166. Moreover, the page that was undergoing a write operation that was not finished at the time the power-off event occurred and the neighboring pages can easily become damaged due to the power-off event.

In view of this, every time a page is filled, the controller 160 will read the data which was currently written into a page of the flash memory 180 and determine whether the pages are damaged according to whether the data can be successfully read. This ensures that the pages are all well and undamaged. The step of determining whether the pages are damaged is called read-check process. In this embodiment, the read-check process will be executed on all the pages of the flash memory 180 right after they are written. The data storage device 140 spends a lot of time performing the read-check process in the background, and this can decrease the performance of the data storage device 140, wherein the read-check process belongs to background.

Therefore, in another embodiment, the controller 160 only executes the read-check process when a predetermined condition is satisfied. It should be noted that, in other embodiments, the unit of the read-check process can be one page or more than one page, but it is not limited thereto. In one of the embodiments, the predetermined condition includes that the written page belongs to the block which was undergoing a write operation which was not finished at the time that a power-off event occurred, but it is not limited thereto. In other embodiments, the predetermined condition further includes that the erase count of the block having the written page is more than a predetermined number, wherein the erase count represents the number of times that the block has been erased, and the predetermined number is determined by the designer according to the characteristics of the flash memory 180. For example, the blocks of the flash memory 180 will normally be damaged after being erased N times, and the predetermined number can be ⅔*N, wherein N is a positive integer. It should be noted that, in this embodiment, all of the written pages of the flash memory 180 have to be processed by the read-check process except for the page which meets the predetermined condition to confirm whether the page is damaged.

More specifically, the controller 160 writes a data sector into a specific page of a specific block of the flash memory 180 according to the command received from the host 120 or other processes. After the data sector is written into the specific page, the controller 160 determines whether the specific block was undergoing a write operation at the time that the power-off event occurred, wherein when any of the pages of the specific block was undergoing a write operation at the time that the power-off event occurred, the controller 160 determines that the specific block was undergoing a write operation at the time that the power-off event occurred. Next, the controller 160 further determines whether to read the data sector from the specific block according to whether the specific block was undergoing a write operation at the time that the power-off event occurred to confirm whether the data sector was successfully written into the specific page, wherein the controller 160 determines that the specific page is not damaged when the data sector was successfully written into the specific page. When the specific block was undergoing a write operation at the time that the power-off event occurred, the controller 160 reads the data sector from the specific page to confirm whether the data sector was successfully written into the specific page (read-check process). When all of the pages of the specific block were not under a power-off event during an unfinished write operation, the controller 160 bypasses the read-check process. Namely, when all of the pages of the specific block were not under a power-off event during an unfinished write operation, the controller 160 will not read the data sector from the specific page and will execute the next task, but it is not limited thereto. In another embodiment, when the specific block was not undergoing a write operation at the time that the power-off event occurred, the controller 160 further determines whether the erase count of the specific block is more than a predetermined number. When the erase count of the specific block is more than the predetermined number, the controller 160 further reads the data sector from the specific page to confirm whether the data sector was successfully written into the specific page. When the erase count of the specific block is not more than the predetermined number, the controller 160 bypasses the read-check process. Namely, when the erase count of the specific block is not more than the predetermined number, the controller 160 processes the next task and does not read the data sector from the specific page, wherein the next task can be a read operation, a write operation, garbage collection, or idle.

In one embodiment, when a specific page is damaged, the controller 160 rewrites the data sector into another available page in the specific block, but it is not limited thereto. In other embodiments, the controller 160 can also rewrite the data sector into another page of another block.

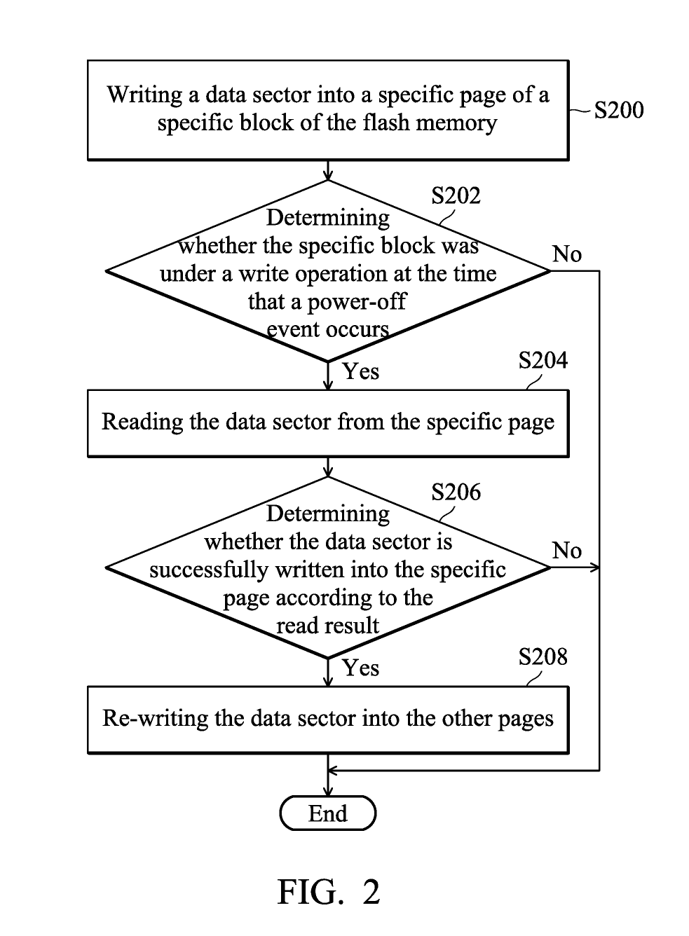

FIG. 2 is a flowchart of a data maintenance method in accordance with an embodiment. The data maintenance method is applied to the data storage device 140 of FIG. 1, and the data maintenance method is arranged to selectively perform the read-check process on a specific page according to whether a specific block having the specific page was undergoing an unfinished write operation at the time that a power-off event occurred. The process starts at step S200.

In step S200, the controller 160 writes a data sector into a specific page of a specific block of the flash memory 180. More specifically, the controller 160 writes the data sector into the specific page of the specific block of the flash memory 180 in response to the command received from the host 120 or other processes.

Next, in step S202, the controller 160 determines whether the specific block was undergoing a write operation at the time that a power-off event occurred. More specifically, when any of the pages of the specific block was undergoing a write operation at the time that a power-off event occurred, the controller 160 determines that the specific block was undergoing a write operation at the time that the power-off event occurred. When the specific block was undergoing a write operation at the time that a power-off event occurred, the process goes to step S204; otherwise, the process ends at step S202.

In step S204, the controller 160 reads the data sector from the specific page.

Next, in step S206, the controller 160 determines whether the data sector was successfully written into the specific page according to the read result. Namely, the controller 160 executes the read-check process on the specific page to confirm whether the specific page is damaged. More specifically, the controller 160 determines that the data sector was successfully written into the specific page when the data sector can be correctly read from the specific page, and the process ends at step S206. When the data sector cannot be successfully read from the specific page, the controller 160 determines that the data sector was not successfully written into the specific page and the specific page might be damaged. When the data sector cannot be successfully read from the specific page, the process goes to step S208.

In step S208, the controller 160 rewrites the data sector into the other pages. More specifically, when a specific page is damaged, the controller 160 rewrites the data sector into another available page in the specific block, but it is not limited thereto. In other embodiments, the controller 160 can also rewrite the data sector into another page of another block. The process ends at step S208.

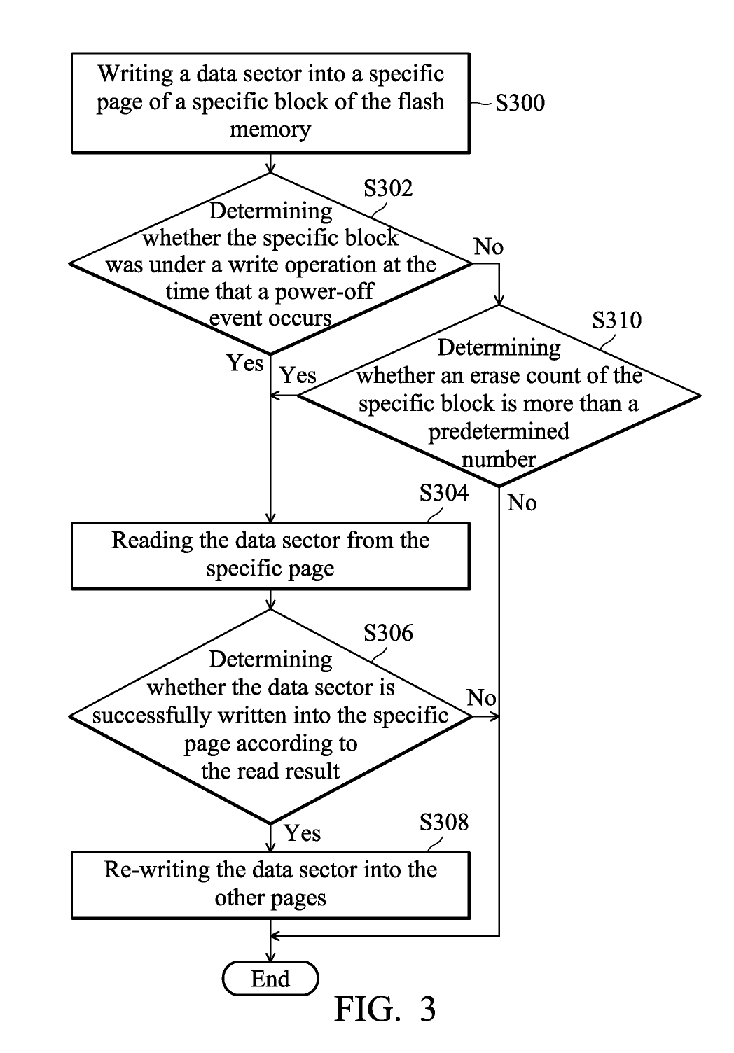

FIG. 3 is a flowchart of a data maintenance method in accordance with another embodiment. The data maintenance method is applied to the data storage device 140 of FIG. 1, and the data maintenance method is arranged to selectively perform the read-check process on a specific page according to whether a specific block having the specific page was undergoing an unfinished write operation at the time that a power-off event occurred. The data maintenance method of FIG. 3 is similar to the data maintenance method of FIG. 2 except that the data maintenance method of FIG. 3 further includes step S310. The details of steps S300˜S308 of the data maintenance method of FIG. 3 can be found by referring to steps S200˜S208.

In step S310, when the specific block was not undergoing a write operation at the time that the power-off event occurred, the controller 160 further determines whether an erase count of the specific block is more than a predetermined number. The predetermined number is determined by the designer according to the characteristics of the flash memory 180. For example, the blocks of the flash memory 180 will normally be damaged after being erased N times, and the predetermined number can be ⅔*N, wherein N is a positive integer. When the erase count of the specific block is more than the predetermined number, the process goes to step S304; otherwise the process ends at step S310.

The data storage device 140 and the data maintenance method of the present invention may selectively execute the read-check process according to whether the specific block was undergoing an unfinished write operation at the time that a power-off event occurred to enhance the write performance of the data storage device.

Data transmission methods, or certain aspects or portions thereof, may take the form of program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes an apparatus for practicing the methods. The methods may also be embodied in the form of program code transmitted over some transmission medium, such as electrical wiring or cabling, through fiber optics, or via any other form of transmission, wherein, when the program code is received and loaded into and executed by a machine such as a computer, the machine becomes an apparatus for practicing the disclosed methods. When implemented on a general-purpose processor, the program code combines with the processor to provide a unique apparatus that operates analogously to application-specific logic circuits.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A data storage device, comprising:
a flash memory, having a plurality of blocks, and each of the blocks has a plurality of pages; and
a controller, writing a data sector into a specific page of a specific block, and determining whether the specific block was undergoing a write operation at the time that a power-off event occurred after the data sector is written into the specific page, wherein the controller determines whether to read the data sector from the specific block according to whether the specific block was undergoing a write operation at the time that the power-off event occurred to confirm whether the data sector was successfully written into the specific page.

2. The data storage device as claimed in claim 1, wherein when the specific block was undergoing a write operation at the time that the power-off event occurred, the controller reads the data sector from the specific page to confirm whether the data sector was successfully written into the specific page.

3. The data storage device as claimed in claim 1, wherein when the specific block was not undergoing a write operation at the time that the power-off event occurred, the controller further determines whether an erase count of the specific block is more than a predetermined number, wherein when the erase count of the specific block is more than the predetermined number, the controller further reads the data sector from the specific page to confirm whether the data sector was successfully written into the specific page.

4. The data storage device as claimed in claim 3, wherein the erase count represents number of times that the specific block has been erased.

5. The data storage device as claimed in claim 3, wherein when the erase count of the specific block is not more than the predetermined number, the controller bypasses the step of reading the data sector from the specific page and performs the next task.

6. A data maintenance method, applied to a data storage device having a flash memory, comprising:
writing a data sector into a specific page of a specific block of the flash memory;
after the data sector is written into the specific page, determining whether the specific block was undergoing a write operation at the time that a power-off event occurred; and
determining whether to read the data sector from the specific block according to whether the specific block was undergoing a write operation at the time that the power-off event occurred to confirm whether the data sector was successfully written into the specific page.

7. The data maintenance method as claimed in claim 6, wherein the step of determining whether to read the data sector from the specific block according to whether the specific block was undergoing a write operation at the time that the power-off event occurred further comprises:
when the specific block was undergoing a write operation at the time that the power-off event occurred, reading the data sector from the specific page to confirm whether the data sector was successfully written into the specific page.

8. The data maintenance method as claimed in claim 6, wherein the step of determining whether to read the data sector from the specific block according to whether the specific block was undergoing a write operation at the time that the power-off event occurred further comprises:
when the specific block was not undergoing a write operation at the time that the power-off event occurred, determining whether an erase count of the specific block is more than a predetermined number, and
when the erase count of the specific block is more than the predetermined number, reading the data sector from the specific page to confirm whether the data sector was successfully written into the specific page.

9. The data maintenance method as claimed in claim 8, wherein the erase count represents the number of times that the specific block has been erased.

10. The data maintenance method as claimed in claim 8, wherein the step of determining whether to read the data sector from the specific block according to whether the specific block was undergoing a write operation at the time that the power-off event occurred further comprises:
when the erase count of the specific block is not more than the predetermined number, bypassing the step of reading the data sector from the specific page and performing the next task.
